(19) United States
(12) Patent Application Publication
(10) Pub. No.: US 2026/0303027 A1
(43) Pub. Date: Oct. 1, 2026

(54) DOHERTY AMPLIFIER CIRCUIT

(71) Applicant: Murata Manufacturing Co., Ltd., Nagaokakyo-shi (JP)

(72) Inventor: Shohei IMAI, Nagaokakyo-shi (JP)

(21) Appl. No.: 19/556,527

(22) Filed: Mar. 4, 2026

(30) Foreign Application Priority Data
Mar. 25, 2025 (JP) 2025-050321

(51) Int. Cl. H03F 1/02; H03F 3/213

(52) U.S. Cl. CPC H03F 1/0288; H03F 3/213; H03F 2200/451

(57) ABSTRACT

A carrier amplifier is configured to amplify a first radio-frequency signal split from an input signal. A peak amplifier is configured to amplify a second radio-frequency signal split from the input signal. A transformer includes a first primary inductor having a first end and a second end, and a first secondary inductor having a third end and a fourth end. An output terminal is connected to a load. The first end is connected to an output node of the carrier amplifier, the second end is connected to the third end and, via a voltage and current conversion circuit, an output node of the peak amplifier, and the fourth end is connected to the output terminal.

### CROSS REFERENCE TO RELATED APPLICATION

This application claims priority from Japanese Patent Application No. 2025-050321, filed on Mar. 25, 2025. The content of these applications are incorporated herein by reference in its entirety.

### BACKGROUND OF THE DISCLOSURE

### 1. Field of the Disclosure

The present disclosure relates to a Doherty amplifier circuit.

### 2. Description of the Related Art

In a modulation method in which the difference between peak power and average power is large, an asymmetric Doherty amplifier that operates with high efficiency is known (E. Kaymaksut and P. Reynaert, “Transformer-Based Uneven Doherty Power Amplifier in 90 nm CMOS for WLAN Applications”, IEEE J. of Solid-State Circuits, vol. 47, no. 7, pp. 1659-1671 July (2012)). In the asymmetric Doherty amplifier described in the above-cited document, two transformers are used to synthesize a radio-frequency signal outputted from a carrier amplifier and a radio-frequency signal outputted from a peak amplifier.

### BRIEF SUMMARY OF THE DISCLOSURE

The asymmetric Doherty amplifier described in the above-cited document includes two transformers. Thus, it is difficult to reduce the size of the amplifier. An object of the present disclosure is to provide a Doherty amplifier circuit suitable for size reduction.

According to an aspect of the present disclosure, the following Doherty amplifier circuit is provided. The Doherty amplifier circuit includes a carrier amplifier configured to amplify a first radio-frequency signal split from an input signal, a peak amplifier configured to amplify a second radio-frequency signal split from the input signal, a transformer including a first primary inductor having a first end and a second end, and a first secondary inductor having a third end and a fourth end, a voltage and current conversion circuit, and an output terminal connected to a load. The first end is connected to an output node of the carrier amplifier, the second end is connected to the third end and, via the voltage and current conversion circuit, an output node of the peak amplifier, and the fourth end is connected to the output terminal. When a voltage directed from the second end toward the first end is generated in the first primary inductor, the transformer has a polarity that allows induction of a voltage directed from the fourth end toward the third end in the first secondary inductor.

The output signal from the carrier amplifier and the output signal from the peak amplifier are synthesized with a single transformer, and accordingly, the Doherty amplifier circuit suitable for size reduction can be realized.

### BRIEF DESCRIPTION OF THE SEVERAL VIEWS OF THE DRAWINGS

FIG. 1 is referred to for explaining a Doherty amplifier circuit according to a first embodiment;

FIG. 2 is a block diagram of a Doherty amplifier circuit according to a second embodiment;

FIG. 3 is a block diagram of a Doherty amplifier circuit according to a comparative example;

FIG. 4A is a graph illustrating a simulation result of frequency dependency of return loss of the Doherty amplifier circuit according to the comparative example illustrated in FIG. 3;

FIG. 4B is a graph illustrating a simulation result of frequency dependency of return loss of the Doherty amplifier circuit according to the second embodiment;

FIG. 5 is a block diagram of a Doherty amplifier circuit according to a comparative example;

FIG. 6 is a block diagram of a Doherty amplifier circuit according to a third embodiment;

FIG. 7 is a graph illustrating a simulation result of the frequency dependency of return loss of the Doherty amplifier circuit according to the third embodiment;

FIG. 8 is a block diagram of a Doherty amplifier circuit according to a fourth embodiment;

FIG. 9 is a block diagram of a Doherty amplifier circuit according to a fifth embodiment; and

FIG. 10 is a block diagram of a Doherty amplifier circuit according to a sixth embodiment.

### DETAILED DESCRIPTION OF THE DISCLOSURE

### First Embodiment

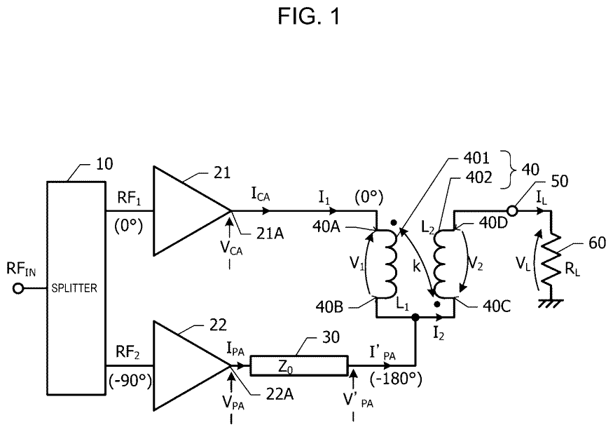

A Doherty amplifier circuit according to a first embodiment will be described below with reference to FIG. 1.

FIG. 1 is a block diagram of the Doherty amplifier circuit according to the first embodiment. The Doherty amplifier circuit according to the first embodiment includes a splitter 10, a carrier amplifier 21, a peak amplifier 22, a voltage and current conversion circuit 30, and a transformer 40. An input signal RF_{IN} is inputted to the splitter 10. The input signal RF_{IN} is a radio-frequency signal at a radio-frequency band. The splitter 10 is configured to split the input signal RF_{IN} into a first radio-frequency signal RF₁ and a second radio-frequency signal RF₂ so that, in one representative frequency in an operating frequency band of the Doherty amplifier circuit, the phase of the second radio-frequency signal RF₂ is delayed by 90° relative to the phase of the first radio-frequency signal RF₁. Referring to FIG. 1, phase delay amounts with reference to the phase of the first radio-frequency signal RF₁ are represented by parenthesized numbers. The minus sign of the phase delay amounts indicates that the phase is delayed relative to the reference phase.

As the operating frequency band, for example, a 3 dB band width can be adopted. It is desired to adopt, for example, a center frequency of the 3 dB band width as the representative frequency. The center frequency is not necessarily adopted as the representative frequency. A frequency included in the 3 dB band width may be adopted as the representative frequency. That is, a frequency at which the phase of the second radio-frequency signal RF₂ is delayed by 90° relative to the phase of the first radio-frequency signal RF exists in the 3 dB band width.

The carrier amplifier 21 is configured to amplify the first radio-frequency signal RF₁, and the peak amplifier 22 is configured to amplify the second radio-frequency signal RF₂. For example, the carrier amplifier 21 is biased in class AB, and the peak amplifier 22 is biased in class C. For example, the carrier amplifier 21 is saturated when a power level of the input signal RF_{IN} is an average power (referred to as a back-off region), and the peak amplifier 22 starts to operate when the power level of the input signal RF_{IN} exceeds the average power. When the power level of the input signal RF_{IN} is a peak power (referred to as a “saturation region”), the peak amplifier 22 is saturated.

The transformer 40 includes a first primary inductor 401 and a first secondary inductor 402. A first end 40A being one of end portions of the first primary inductor 401 is connected to an output node 21A of the carrier amplifier 21. A second end 40B being another end portion of the first primary inductor 401 is connected to a third end 40C being one of end portions of the first secondary inductor 402. A fourth end 40D being another end portion of the first secondary inductor 402 is connected to an output terminal 50 of the Doherty amplifier circuit. A load 60 is connected between the output terminal 50 and the ground. The load 60 includes, for example, an antenna. When a voltage V₁ directed from the second end 40B toward the first end 40A is generated in the first primary inductor 401, the transformer 40 has a polarity that allows induction of a voltage V₂ directed from the fourth end 40D toward the third end 40C in the first secondary inductor 402.

The second end 40B of the transformer 40 is further connected to an output node 22A of the peak amplifier 22 via the voltage and current conversion circuit 30. A quarter-wave line is used as the voltage and current conversion circuit 30. The line length of the quarter-wave line is a quarter of the wavelength of the radio-frequency signal of the representative frequency. Accordingly, when the radio-frequency signal of the representative frequency passes through the voltage and current conversion circuit 30, a phase delay of 90° is produced.

The maximum output power of the peak amplifier 22 is greater than the maximum output power of the carrier amplifier 21. Such a Doherty amplifier circuit is referred to as an asymmetric Doherty amplifier circuit. The asymmetric Doherty amplifier circuit can operate with high efficiency particularly when a modulation method with a high peak-to-average power ratio (PAPR) of the input signal RF_{IN} is used.

The output of a transistor used for the carrier amplifier 21 and the output of a transistor used for the peak amplifier 22 are generally regarded as current sources. When the voltage and current conversion circuit 30 is connected to the output node of the peak amplifier 22, the peak amplifier 22 including the voltage and current conversion circuit 30 can be regarded as a voltage source. Accordingly, in the case where the peak amplifier 22 is not operated, an output impedance, which looks at the peak amplifier 22 side from the output end of the voltage and current conversion circuit 30, is lower than an output impedance of the carrier amplifier 21 that can be regarded as the current source. Thus, among the power of the radio-frequency signal outputted from the carrier amplifier 21, the power to be consumed by the peak amplifier 22 decreases, and the power is efficiently supplied to the load 60.

Next, various parameters of the Doherty amplifier circuit according to the first embodiment are described.

A voltage of the output node of the carrier amplifier 21 is represented as V_{CA} and an output current is represented as I_{CA}. A voltage of the output node of the peak amplifier 22 is represented as V_{PA} and an output current is represented as I_{PA}. A characteristic impedance of the quarter-wave line included in the voltage and current conversion circuit 30 is represented as Z₀. A current flowing from the first end 40A toward the second end 40B through the first primary inductor 401 of the transformer 40 is represented as I₁, and a current flowing from the third end 40C toward the fourth end 40D through the first secondary inductor 402 of the transformer 40 is represented as current I₂. A voltage of the output terminal 50 is represented as V_{L}, and an output current from the output terminal 50 is represented as I_{L}. An impedance of the load 60 is represented as R_{L}. The voltage V_{CA} is equal to the sum of the voltages V_{L}, V₂, and V₁.

When inductances of the first primary inductor 401 and the first secondary inductor 402 of the transformer 40 are respectively represented as L₁ and L₂, a winding ratio n of the transformer 40 is defined as n²=L₂/L₁. The transformer 40 is assumed as an ideal transformer having a coupling factor k=1.

The voltage V_{CA} of the output node of the carrier amplifier 21 is given by the following expression.

$${V}_{CA} = - \frac{{R}_{L}}{n} {I}_{1} + ( 1 + n ) {V}_{1} \qquad ( 1 )$$

The following expression holds due to a relational expression of the quarter-wave line.

$${V}_{PA}^{′} = - {jZ}_{0} {I}_{PA} \qquad ( 2 )$$

Here, j is an imaginary unit when an alternating current is represented by a complex number. A voltage V′_{PA} is given by the following expression.

$${V}_{PA}^{′} = {V}_{L} + {V}_{2} = - \frac{{R}_{L}}{n} {I}_{1} + {nV}_{1} \qquad ( 3 )$$

The following expression is derived from expression (2) and expression (3).

$${V}_{1} = - \frac{{jZ}_{0}}{n} {I}_{PA} + \frac{{R}_{L}}{{n}^{2}} {I}_{1} \qquad ( 4 )$$

The following expression is derived from expression (1) and expression (4).

$${V}_{CA} = \frac{{R}_{L}}{{n}^{2}} {I}_{1} - \frac{( 1 + n ) {jZ}_{0}}{n} {I}_{PA} \qquad ( 5 )$$

The following expression holds due to a relational expression of the quarter-wave line.

$${V}_{PA} = {jZ}_{0} {I}_{PA}^{′} = - {jZ}_{0} ( {I}_{1} - {I}_{2} ) \qquad ( 6 )$$

When the current I₂ is represented by I₁ by using the relational expression of the transformer 40, and further, I₁=I_{CA}, the following expression is derived.

$${V}_{PA} = - {jZ}_{0} \frac{1 + n}{n} {I}_{CA} \qquad ( 7 )$$

The impedance Z_{PA}, which looks at the load side from the output node of the peak amplifier 22, is given by the following expression.

$${Z}_{PA} = \frac{{V}_{PA}}{{I}_{PA}} = - {jZ}_{0} \frac{1 + n}{n} \frac{{I}_{CA}}{{I}_{PA}} = {Z}_{0} \frac{1 + n}{n} \frac{1}{\vert γ \vert} \qquad ( 8 )$$

Here, |γ| is defined by the following expression.

$${I}_{PA} = - j \vert γ \vert {I}_{CA} \qquad ( 9 )$$

That is, |γ| is a ratio of the output current I_{PA} of the peak amplifier 22 to the output current I_{CA} of the carrier amplifier 21.

From expression (5), the impedance Z_{CA}, which looks at the load side from the output node of the carrier amplifier 21, is given by the following expression.

$${Z}_{CA} = \frac{{V}_{CA}}{{I}_{CA}} = \frac{{R}_{L}}{{n}^{2}} - \frac{( 1 + n ) {jZ}_{0}}{{I}_{CA}} \frac{{I}_{PA}}{{I}_{CA}} = \frac{{R}_{L}}{{n}^{2}} - \frac{( 1 + n ) {Z}_{0}}{n} \vert γ \vert \qquad ( 10 )$$

It is desirable to determine the values of the parameters so that the impedances Z_{PA} and Z_{CA} given by expressions (8) and (10) are coincident with an output impedance determined by the transistors included in the carrier amplifier 21 and the peak amplifier 22 and the bias conditions so as to realize impedance matching.

A target impedance of the carrier amplifier 21 in the saturation region is represented as Z_{OPT}. Parameter α is defined by the following expression.

$$α = \frac{{I}_{PMAX}}{{I}_{CMAX}} \qquad ( 11 )$$

Here, I_{PMAX} is a maximum output current of the peak amplifier 22, and I_{CMAX} is a maximum output current of the carrier amplifier 21. The parameter α corresponds to the ratio between the area of the transistor included in the peak amplifier 22 and the area of the transistor included in the carrier amplifier 21. The asymmetric Doherty amplifier circuit is designed so that α is normally greater than 1.

The target impedance Z_{OPT} of the carrier amplifier 21 is determined so as to obtain impedance matching in the saturation region. That is, when the output current of the carrier amplifier 21 is I_{CMAX} and the output current of the peak amplifier 22 is I_{PMAX}, the impedance matching is obtained. In the back-off region without output from the peak amplifier 22, that is, when γ=0, the output current of the carrier amplifier 21 is I_{CMAX}, and the output current from the peak amplifier 22 is zero. Thus, the total output current decreases to 1/(1+α) times compared to that in the saturation region. For this reason, the output impedance of the carrier amplifier 21 may match with (1+α)Z_{OPT} in the back-off region.

When γ=0, from expression (10), the impedance Z_{CA} is given by the following expression.

$${Z}_{CA} {\vert}_{γ = 0} = \frac{{R}_{L}}{{n}^{2}} \qquad ( 12 )$$

When the impedance Z_{CA} for γ=0 matches with (1+α)Z_{OPT}, the following expression is derived.

$${n}^{2} = \frac{{R}_{L}}{( 1 + α ) {Z}_{OPT}} \qquad ( 13 )$$

That is, the winding ratio n of the transformer 40 can be determined by the impedance R_{L} of the load 60, the target impedance Z_{OPT} of the carrier amplifier 21 in the saturation region, and the parameter α.

In the saturation region, that is, when γ=α, from expressions (10) and (13), the impedance Z_{CA} can be given by the following expression.

$${Z}_{CA} {I}_{γ = α} = ( 1 + α ) {Z}_{OPT} - \frac{( 1 + n ) {Z}_{0}}{n} α \qquad ( 14 )$$

The target impedance of the carrier amplifier 21 in the saturation region is Z_{OPT}. Thus, the right side of expression (14) is equal to Z_{OPT}. Accordingly, the target impedance Z_{OPT} is given by the following expression.

$${Z}_{OPT} = {Z}_{0} \frac{1 + n}{n} \qquad ( 15 )$$

From expression (15), it can be understood that the characteristic impedance Z₀ of the quarter-wave line included in the voltage and current conversion circuit 30 is designed so as to satisfy the following expression.

$${Z}_{0} = \frac{n}{1 + n} {Z}_{OPT} \qquad ( 16 )$$

The above description is one of guidelines for determining the various parameters of the Doherty amplifier circuit. It is not required that the above-described relational expressions of the various parameters be exactly satisfied.

Next, an effect of the first embodiment is described.

According to the first embodiment, the output signal from the carrier amplifier 21 and the output signal from the peak amplifier 22 can be synthesized with a single transformer 40. Thus, the configuration according to the first embodiment suits size reduction compared to a configuration in which transformers are respectively connected to an output node of the carrier amplifier 21 and an output node of the peak amplifier 22.

The following expression holds among currents I_{PA}′, I₁, I₂, and I_{CA}.

$${I}_{PA}^{′} = {I}_{2} - {I}_{1} = {I}_{2} ( 1 + n ) = - {I}_{1} \frac{1 + n}{n} = - {I}_{CA} \frac{1 + n}{n} \qquad ( 17 )$$

From expression (17), it can be understood that the synthesis can be asymmetrically performed so that the current on the peak amplifier 22 side is greater than the current on the carrier amplifier 21 side. In general, the peak amplifier 22 includes a greater transistor than a transistor included in the carrier amplifier 21. Accordingly, the current flowing through the peak amplifier 22 is greater than the current flowing through the carrier amplifier 21. According to the first embodiment, such an asymmetric synthesis of the current is easily achieved.

### Second Embodiment

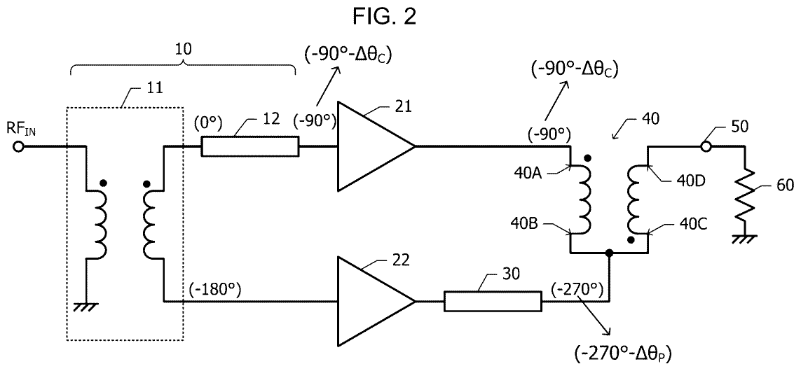

Next, a Doherty amplifier circuit according to a second embodiment is described with reference to FIG. 2. In the following, description of elements shared with the Doherty amplifier circuit according to the first embodiment having been described with reference to FIG. 1 is omitted.

FIG. 2 is a block diagram of the Doherty amplifier circuit according to the second embodiment. The second embodiment makes the configuration of the splitter 10 more specific. The splitter 10 of the Doherty amplifier circuit according to the second embodiment includes a phase reversal splitter 11 and a first transmission line 12. The phase reversal splitter 11 is configured to split the input signal RF_{IN} and output, from two output nodes, radio-frequency signals with a phase difference of 180° at the representative frequency. One of the output nodes of the phase reversal splitter 11 is connected to an input node of the peak amplifier 22, and the other output node of the phase reversal splitter 11 is connected to an input node of the carrier amplifier 21 via the first transmission line 12. For example, relative to the phase of the radio-frequency signal at an input end of the first transmission line 12, the phase delay amount of the radio-frequency signal at the input node of the peak amplifier 22 is −180°.

The first transmission line 12 is a quarter-wave line having a line length of a quarter of the wavelength at the representative frequency. Thus, the phase delay amount of the radio-frequency signal at an output end of the first transmission line 12 is −90°. Also, the phase delay amount of the radio-frequency signal at the first end 40A of the transformer 40 is −90°.

The phase delay amount of the radio-frequency signal at an input end of the voltage and current conversion circuit 30 is −180°. Thus, the phase delay amount of the radio-frequency signal at an output end of the voltage and current conversion circuit 30 is −270°. Accordingly, the phase difference of the radio-frequency signal between the first end 40A and the second end 40B of the transformer 40 is, as is the case with the first embodiment (FIG. 1), 180°.

Next, an effect of the second embodiment is described.

According to the second embodiment, a voltage amplitude is reduced at the output end of the voltage and current conversion circuit 30 as is the case with the first embodiment. Thus, in the asymmetric configuration in which the maximum output power of the peak amplifier 22 is greater than the maximum output power of the carrier amplifier 21, two radio-frequency signals can be efficiently synthesized.

The spectrum of the input signal RF_{IN} extends in a certain frequency range including the representative frequency. Hereinafter, the delay of the phase of the radio-frequency signal having a frequency shifted from the representative frequency is described. An increase in the frequency of the radio-frequency signal to be transmitted increases the phase delay due to the voltage and current conversion circuit 30 being a quarter-wave line. When this increase in phase delay is represented as Δθ_{P}, the phase delay amount is −270°−Δθ_{P} at the output end of the voltage and current conversion circuit 30 (the second end 40B of the transformer 40).

When the frequency of the radio-frequency signal to be transmitted increases from the representative frequency, an increase amount of the phase delay due to the first transmission line 12 is represented as Δθ_{C}. At this time, the phase delay amount of the radio-frequency signal at the input node of the carrier amplifier 21 is −90°−Δθ_{C}. Accordingly, the phase delay amount at the first end 40A of the transformer 40 is also −90°−Δθ_{C}.

The phase reversal splitter 11 does not have a frequency dependency. Thus, even for the radio-frequency signal having a frequency shifted from the representative frequency, the phase delay amount at the input node of the peak amplifier 22 is still −180°.

When the increase amount Δθ_{C} of the phase delay amount on the carrier amplifier 21 side is equal to the increase amount Δθ_{P} of the phase delay amount on the peak amplifier 22 side, the difference in phase delay amount between the first end 40A and the second end 40B of the transformer 40 is maintained at 180° also for the radio-frequency signal of the frequency shifted from the representative frequency. Even when the increase amounts in phase delay Δθ_{C} and Δθ_{P} are not equal to each other, these amounts partially cancel out each other. This reduces the amount of shift of the phase difference of the radio-frequency signal from 180° between the first end 40A and the second end 40B of the transformer 40. Thus, a broad band can be obtained.

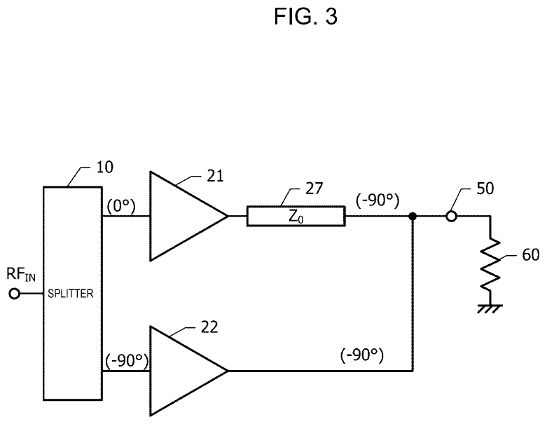

Next, compared to a comparative example illustrated in FIG. 3, an effect of the second embodiment is described.

FIG. 3 is a block diagram of a Doherty amplifier circuit according to the comparative example. In the Doherty amplifier circuit according to the comparative example illustrated in FIG. 3, a quarter-wave line 27 is connected between the output node of the carrier amplifier 21 and the output terminal 50. The output node of the peak amplifier 22 is connected to the output terminal 50. The phase of the radio-frequency signal inputted to the peak amplifier 22 is delayed by 90° relative to the phase of the radio-frequency signal inputted to the carrier amplifier 21. The phase delay of 90° occurs due to the quarter-wave line 27. Thus, the radio-frequency signal outputted from the carrier amplifier 21 and the radio-frequency signal outputted from the peak amplifier 22 are in phase with each other at the output terminal 50 and synthesized.

The characteristic impedance Z₀ of the quarter-wave line 27 is coincident with the target impedance Z_{OPT} of the carrier amplifier 21. Furthermore, in order to maintain the impedance matching in the saturation region, the target impedance Z_{OPT} is set to be 1+α times the load impedance R_{L}.

When the radio-frequency signal of a frequency shifted from the representative frequency is transmitted, the phase delay due to the quarter-wave line 27 increases. In contrast, the phase delay amount at the output node of the peak amplifier 22 does not change. Thus, the radio-frequency signal amplified by the carrier amplifier 21 and the radio-frequency signal amplified by the peak amplifier 22 are out of phase with each other at the output terminal 50.

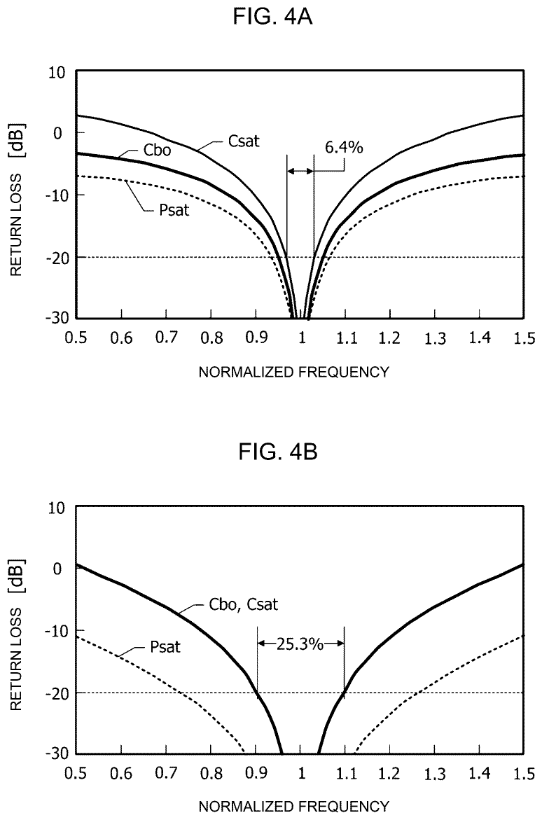

FIG. 4A is a graph illustrating a simulation result of the frequency dependency of return loss of the Doherty amplifier circuit according to the comparative example illustrated in FIG. 3. FIG. 4B is a graph illustrating a simulation result of the frequency dependency of return loss of the Doherty amplifier circuit according to the second embodiment. The horizontal axis represents a normalized frequency, and the vertical axis represents the return loss in dB. The normalized frequency is normalized with a frequency for which the line length of the quarter-wave line included in the voltage and current conversion circuit 30 of the second embodiment and the line length of the quarter-wave line 27 according to the comparative example (FIG. 3) are a quarter wavelength.

Solid lines Cbo and Csat illustrated in FIGS. 4A and 4B indicate the return loss of the radio-frequency signal outputted from the carrier amplifier 21 when the Doherty amplifier circuit is operated in the back-off region and the saturation region, respectively. A broken line Psat indicates the return loss of the radio-frequency signal outputted from the peak amplifier 22 when the Doherty amplifier circuit is operated in the saturation region. It is considered that the impedance matching is obtained in a range in which the return loss is smaller than or equal to −20 dB.

In the comparative example illustrated in FIG. 4A, a matching fractional bandwidth is about 6.4%. In the second embodiment illustrated in FIG. 4B, a matching fractional bandwidth is about 25.38. The reason the matching fractional bandwidth is narrowed in the comparative example (FIG. 4A) is that, at a frequency shifted from the representative frequency, the radio-frequency signal amplified by the carrier amplifier 21 and the radio-frequency signal amplified by the peak amplifier 22 are out of phase with each other at the position of the output terminal 50. According to the second embodiment, the amounts of shift of the phases of two radio-frequency signals cancel out each other, and accordingly, a broad band can be obtained.

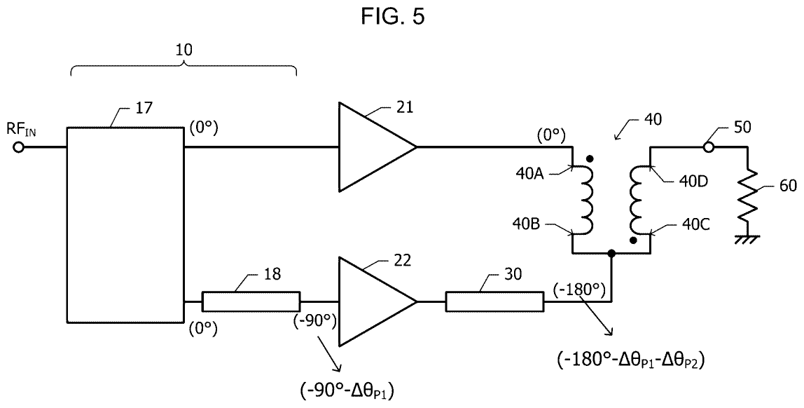

Next, compared to a comparative example illustrated in FIG. 5, an effect of the second embodiment is described.

FIG. 5 is a block diagram of a Doherty amplifier circuit according to the comparative example. According to the comparative example illustrated in FIG. 5, an in-phase splitter 17 splits the input signal RF_{IN} into two radio-frequency signals in phase with each other. One of the radio-frequency signals is inputted to the carrier amplifier 21, and the other radio-frequency signal is inputted to the peak amplifier 22 via a quarter-wave line 18. The phase delay amount of the radio-frequency signal at the input node of the peak amplifier 22 is −90°. The phase delay amount of the radio-frequency signal at the output end of the voltage and current conversion circuit 30 is −180°. Accordingly, the phase difference of the radio-frequency signal between the first end 40A and the second end 40B of the transformer 40 is, as is the case with the second embodiment (FIG. 2), 180°.

Next, the phase delay of the radio-frequency signal having a frequency shifted from the representative frequency is described. An increase in the frequency of the radio-frequency signal to be transmitted increases the phase delay amount due to the quarter-wave line 18. When this increase amount in phase delay is represented as Δθ_{P1}, the phase delay amount is −90°−Δθ_{P1} at an output end of the quarter-wave line 18. Furthermore, when an increase amount in phase delay due to the voltage and current conversion circuit 30 including the quarter-wave line is represented as Δθ_{P2}, the phase delay amount is −180°−Δθ_{P1}−Δθ_{P2} at the output end of the voltage and current conversion circuit 30. In contrast, no transmission line causing the phase delay is inserted in a transmission path including the carrier amplifier 21 from the in-phase splitter 17 to the transformer 40. Thus, even when the frequency is shifted from the representative frequency, the phase delay amount of the radio-frequency signal at the first end 40A of the transformer 40 is still 0°.

Accordingly, for the radio-frequency signal at a frequency shifted from the representative frequency, the phase difference between the first end 40A and the second end 40B changes from 180°. As a result, on condition that the frequency is shifted from the representative frequency, the radio-frequency signal from the carrier amplifier 21 and the radio-frequency signal from the peak amplifier 22 cannot be efficiently synthesized. Thus, it is difficult to obtain a broad band.

In contrast, according to the second embodiment, the phase difference of the radio-frequency signal between the first end 40A and the second end 40B of the transformer 40 is maintained at about 180°. Thus, a broad band can be obtained.

### Third Embodiment

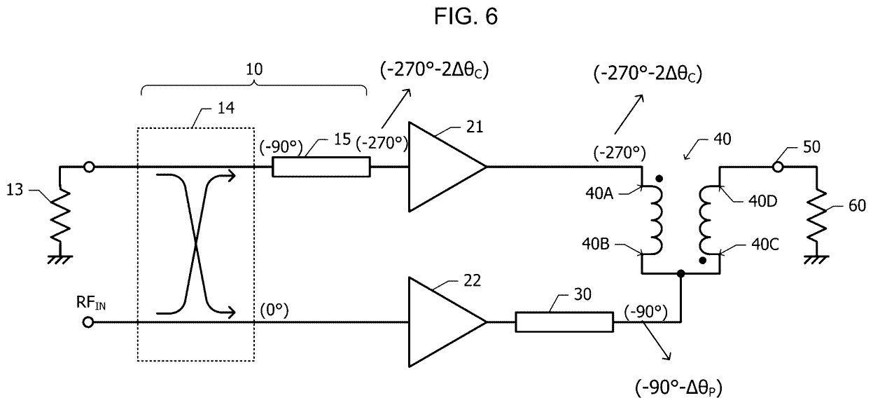

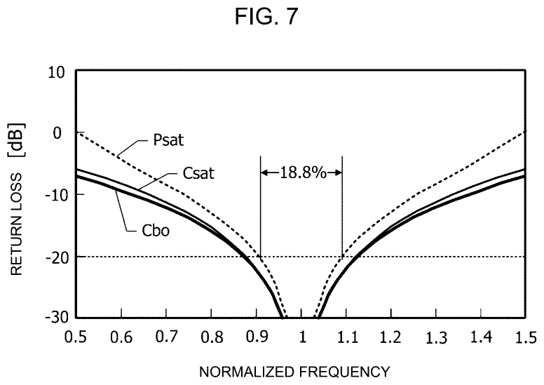

Next, a Doherty amplifier circuit according to a third embodiment is described with reference to FIGS. 6 and 7. In the following, description of elements shared with the Doherty amplifier circuit according to the second embodiment illustrated in FIG. 2 is omitted.

FIG. 6 is a block diagram of the Doherty amplifier circuit according to the third embodiment. According to the third embodiment, the phase reversal splitter 11 of the second embodiment (FIG. 2) is replaced with a 90-degree hybrid coupler 14, and the first transmission line 12 including the quarter-wave line (FIG. 2) is replaced with a second transmission line 15 including a half-wave line. The 90-degree hybrid coupler 14 includes two input nodes and two output nodes. A non-reflective termination resistor 13 is connected to one of the input nodes, and the input signal RF_{IN} is inputted from the other input node.

Radio-frequency signals with a phase difference of 90° at the representative frequency are outputted from two output nodes. An output node from which a radio-frequency signal of an advanced phase is outputted is connected to the input node of the peak amplifier 22, and an output node from which a radio-frequency signal of a delayed phase is outputted is connected to the input node of the carrier amplifier 21 via the second transmission line 15.

For example, relative to the phase of the radio-frequency signal inputted to the peak amplifier 22, the phase delay amount of the radio-frequency signal at an input end of the second transmission line 15 is −90°. The 90-degree hybrid coupler 14 does not have a frequency dependency. Even when the frequency is shifted from the representative frequency, the phase difference between the radio-frequency signals outputted from two output nodes is still 90°.

The second transmission line 15 is a half-wave line having a line length of half the wavelength at the representative frequency. Thus, the phase delay amount of the radio-frequency signal at an output end of the second transmission line 15 is −270°. The phase delay amount of the radio-frequency signal at the output end of the voltage and current conversion circuit 30 is −90°. Accordingly, the phase difference of the radio-frequency signal between the first end 40A and the second end 40B of the transformer 40 is, as is the case with the second embodiment (FIG. 2), 180°.

Next, an effect of the third embodiment is described. On condition that the frequency rises from the representative frequency, the increase amount in phase difference in the first transmission line 12 being the quarter-wave line illustrated in FIG. 2 is Δθ_{C}. Thus, an increase amount in phase delay due to the second transmission line 15 being the half-wave line is 2Δθ_{C}. Accordingly, the phase delay amount of the radio-frequency signal at the first end 40A of the transformer 40 is −270°−2Δθ_{C}.

The increase amount in phase delay due to the voltage and current conversion circuit 30 is, similar to the case illustrated in FIG. 2, 40p. Accordingly, the phase delay amount at the second end 40B of the transformer 40 is −90°−Δ←^{P}.

When the frequency is shifted from the representative frequency, the increase amount 240c in phase delay at the first end 40A and the increase amount Δθ_{P} in phase delay at the second end 40B partially cancel out each other. Thus, the broad band characteristics can be obtained.

FIG. 7 is a graph illustrating a simulation result of the frequency dependency of return loss of the Doherty amplifier circuit according to the third embodiment. The horizontal axis represents a normalized frequency, and the vertical axis represents the return loss in dB. The normalized frequency is normalized with a frequency for which the line length of the quarter-wave line included in the voltage and current conversion circuit 30 is a quarter wavelength.

Solid lines Cbo and Csat illustrated in FIG. 7 indicate the return loss of the radio-frequency signal outputted from the carrier amplifier 21 when the Doherty amplifier circuit is operated in the back-off region and the saturation region, respectively. A broken line Psat indicates the return loss of the radio-frequency signal outputted from the peak amplifier 22 when the Doherty amplifier circuit is operated in the saturation region. It is considered that the impedance matching is obtained when the return loss is smaller than or equal to −20 dB. At this time, a matching fractional bandwidth is about 18.8%. Thus, it is understood that, compared to the matching fractional bandwidth of 6.4% with the Doherty amplifier circuit according to the comparative example illustrated in FIGS. 3 and 4A, a broad band is realized.

### Fourth Embodiment

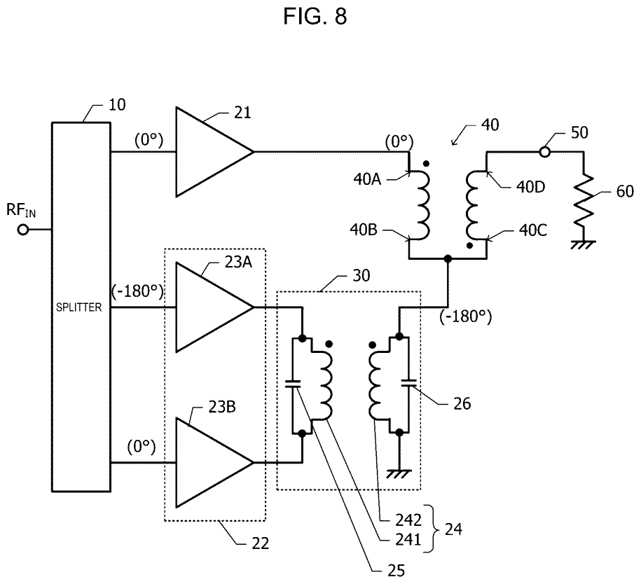

Next, a Doherty amplifier circuit according to a fourth embodiment is described with reference to FIG. 8. In the following, description of elements shared with the Doherty amplifier circuit according to the first embodiment illustrated in FIG. 1 is omitted.

FIG. 8 is a block diagram of the Doherty amplifier circuit according to the fourth embodiment. According to the first embodiment (FIG. 1), the peak amplifier 22 amplifies single-ended signals. In contrast, according to the fourth embodiment, the peak amplifier 22 is a differential amplifier including an amplifier 23A and an amplifier 23B. A radio-frequency signal in phase with the radio-frequency signal inputted to the carrier amplifier 21 is inputted to the amplifier 23B. A radio-frequency signal of an opposite phase relative to the radio-frequency signal inputted to the carrier amplifier 21 is inputted to the amplifier 23A.

Although the quarter-wave line is used as the voltage and current conversion circuit 30 according to the first embodiment (FIG. 1), the voltage and current conversion circuit 30 includes a peak-amplifier transformer 24 according to the fourth embodiment. A second primary inductor 241 of the peak-amplifier transformer 24 is connected between an output node of the amplifier 23A for an opposite-phase signal and an output node of the amplifier 23B for an in-phase signal. One end of a second secondary inductor 242 of the peak-amplifier transformer 24 is connected to the second end 40B of the transformer 40 and the other end of the second secondary inductor 242 is connected to the ground. When a voltage directed from the output node of the amplifier 23B for an in-phase signal toward the output node of the amplifier 23A for an opposite-phase signal is generated in the second primary inductor 241, the peak-amplifier transformer 24 has a polarity that allows generation of a voltage directed from the ground toward the second end 40B in the second secondary inductor 242.

A first input-side capacitor 25 is connected in parallel with the second primary inductor 241 of the peak-amplifier transformer 24, and a first output-side capacitor 26 is connected in parallel with the second secondary inductor 242 of the peak-amplifier transformer 24. A circuit including the peak-amplifier transformer 24, the first input-side capacitor 25, and the first output-side capacitor 26 functions as, as is the case with the quarter-wave line, a voltage and current conversion circuit. The operating principle of this voltage and current conversion circuit 30 is described in, for example, Japanese Unexamined Patent Application Publication No. 2021-192476. In this configuration, the phase delay amount of the radio-frequency signal at the second end 40B of the transformer 40 is-180°.

Next, an effect of the fourth embodiment is described. According to the fourth embodiment, output can be increased by synthesizing the output of the amplifier 23A for an opposite-phase signal and the amplifier 23B for an in-phase signal. That is, an asymmetric Doherty amplifier circuit is obtained. Also, according to the fourth embodiment, as is the case with the first embodiment, in the asymmetric configuration in which the maximum output power of the peak amplifier 22 is greater than the maximum output power of the carrier amplifier 21, two radio-frequency signals can be efficiently synthesized.

Furthermore, according to the fourth embodiment, the quarter-wave line is not used as the voltage and current conversion circuit 30. Thus, the size of the circuit can be reduced without depending on the wavelength of the input signal RF_{IN}.

Next, a modification of the fourth embodiment is described.

Although the differential amplifier is used for the peak amplifier 22 according to the fourth embodiment, an amplifier configured to amplify single-ended signals can be used for the peak amplifier 22. In this case, only the amplifier 23A for an opposite-phase signal having a large output can be used, and the amplifier 23B for an in-phase signal can be omitted. At this time, one end of the second primary inductor 241 (end portion connected to the amplifier 23B) can be connected to the ground.

### Fifth Embodiment

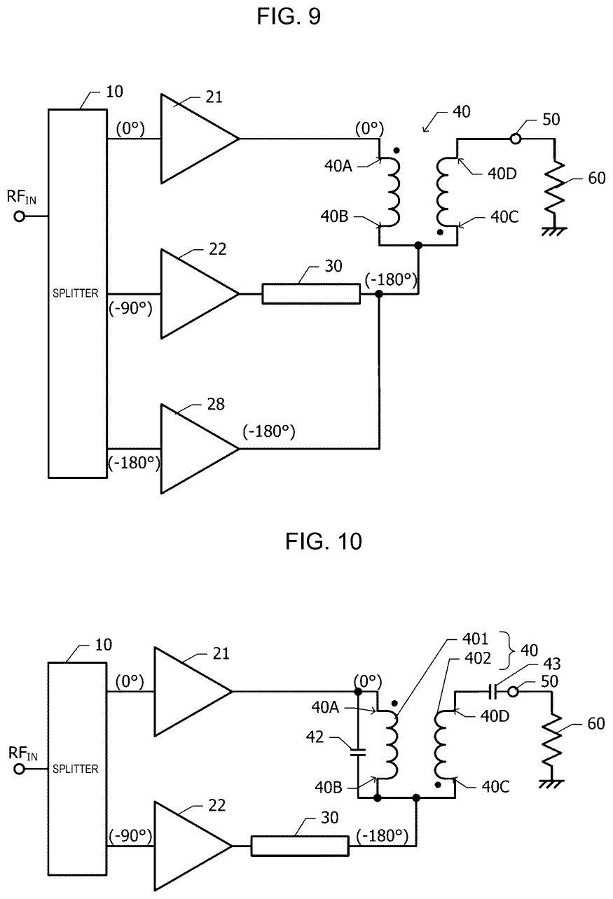

Next, a Doherty amplifier circuit according to a fifth embodiment is described with reference to FIG. 9. In the following, description of elements shared with the Doherty amplifier circuit according to the first embodiment illustrated in FIG. 1 is omitted.

FIG. 9 is a block diagram of the Doherty amplifier circuit according to the fifth embodiment. The Doherty amplifier circuit according to the fifth embodiment includes a high-level peak amplifier 28 in addition to the elements of the Doherty amplifier circuit according to the first embodiment (FIG. 1). The power level of the input signal RF_{IN} at the time when the high-level peak amplifier 28 starts an amplifying operation (operation starting power level) is higher than the operation starting power level of the peak amplifier 22.

For example, the high-level peak amplifier 28 starts the amplifying operation when the peak amplifier 22 reaches a saturated state. An output node of the high-level peak amplifier 28 is connected to the output end of the voltage and current conversion circuit 30, that is, the second end 40B of the transformer 40. The Doherty amplifier circuit according to the fifth embodiment is a multi-way Doherty amplifier circuit.

Relative to the phase of the radio-frequency signal inputted to the carrier amplifier 21, the splitter 10 causes the phase delay amount of the radio-frequency signal inputted to the peak amplifier 22 to be −90° and the phase delay amount of the radio-frequency signal inputted to the high-level peak amplifier 28 to be −180°. At the output end of the voltage and current conversion circuit 30, both the phase delay amount of the radio-frequency signal amplified by the peak amplifier 22 and the phase delay amount of the radio-frequency signal amplified by the high-level peak amplifier 28 are −180°. The total of the maximum output power of the peak amplifier 22 and the maximum output power of the high-level peak amplifier 28 is greater than the maximum output power of the carrier amplifier 21. That is, an asymmetric Doherty amplifier circuit is formed by the carrier amplifier 21, the peak amplifier 22, and the high-level peak amplifier 28.

Next, an effect of the fifth embodiment is described.

According to the fifth embodiment, the low-level peak amplifier 22 reaches the saturated state before the high-level peak amplifier 28 reaches the saturated state. A highly efficient operation of the peak amplifier 22 can be performed in this saturation region of the peak amplifier 22.

### Sixth Embodiment

Next, a Doherty amplifier circuit according to a sixth embodiment is described with reference to FIG. 10. In the following, description of elements shared with the Doherty amplifier circuit according to the first embodiment illustrated in FIG. 1 is omitted.

FIG. 10 is a block diagram of the Doherty amplifier circuit according to the sixth embodiment. The Doherty amplifier circuit according to the sixth embodiment includes a second input-side capacitor 42 and a second output-side capacitor 43 in addition to the elements of the Doherty amplifier circuit according to the first embodiment (FIG. 1). The second input-side capacitor 42 is connected between the first end 40A and the second end 40B of the transformer 40. The second output-side capacitor 43 is connected between the fourth end 40D of the transformer 40 and the output terminal 50. That is, the second input-side capacitor 42 is connected in series with the first primary inductor 401 of the transformer 40, and the second output-side capacitor 43 is connected in series with the first secondary inductor 402 of the transformer 40.

The circuit constant is selected so that, at the representative frequency, parallel resonance is caused between the first primary inductor 401 and the second input-side capacitor 42 and series resonance is caused between the first secondary inductor 402 and the second output-side capacitor 43 resonate.

Next, an effect of the sixth embodiment is described.

At the representative frequency, parallel resonance is caused between the first primary inductor 401 and the second input-side capacitor 42 and series resonance is caused between the first secondary inductor 402 and the second output-side capacitor 43 resonate. Thus, operation similar to the ideal transformer can be realized.

The above-described embodiments are merely exemplary, and it goes without saying that partial replacement or combination of configurations described in the different embodiments is possible. Similar functions or effects achieved by similar configurations among the plurality of embodiments are not described repeatedly for each embodiment. The present disclosure is not limited to the above-described embodiments. For example, it will be apparent to those skilled in the art that various changes, improvements, combinations, and the like are possible.

What is claimed is:

1. A Doherty amplifier circuit comprising:
a carrier amplifier configured to amplify a first radio-frequency signal split from an input signal;
a peak amplifier configured to amplify a second radio-frequency signal split from the input signal;
a transformer comprising:
a first primary inductor having a first end and a second end, and
a first secondary inductor having a third end and a fourth end;
a voltage and current conversion circuit; and
an output terminal connected to a load,
wherein the first end is connected to an output node of the carrier amplifier, the second end is connected to the third end and to an output node of the peak amplifier via the voltage and current conversion circuit, and the fourth end is connected to the output terminal, and
wherein, when a voltage directed from the second end toward the first end is generated in the first primary inductor, the transformer has a polarity that allows induction of a voltage directed from the fourth end toward the third end in the first secondary inductor.

2. The Doherty amplifier circuit according to claim 1, further comprising:
a splitter configured to split, in one representative frequency in an operating frequency band, the input signal into the first radio-frequency signal and the second radio-frequency signal so that a phase of the second radio-frequency signal is delayed by 90 degrees relative to a phase of the first radio-frequency signal.

3. The Doherty amplifier circuit according to claim 2,
wherein the splitter comprises:
a phase reversal splitter configured to split the input signal and output from two output nodes, and
a first transmission line having a line length of a quarter of a wavelength of the representative frequency,
wherein the voltage and current conversion circuit comprises a transmission line having a line length of a quarter of a wavelength of the representative frequency, and
wherein the phase reversal splitter is configured to output, from the two output nodes, radio-frequency signals with a phase difference of 180 degrees at the representative frequency, a first of the output nodes of the phase reversal splitter being connected to an input node of the peak amplifier, and a second of the output nodes of the phase reversal splitter being connected to an input node of the carrier amplifier via the first transmission line.

4. The Doherty amplifier circuit according to claim 2,
wherein the splitter comprises:
a 90-degree hybrid coupler configured to split the input signal and output from two output nodes, and
a second transmission line having a line length of half a wavelength of the representative frequency,
wherein the voltage and current conversion circuit comprises a transmission line having a line length of a quarter of a wavelength of the representative frequency,
wherein the 90-degree hybrid coupler is configured to output, from the two output nodes, radio-frequency signals with a phase difference of 90 degrees at the representative frequency,
wherein the output node of the 90-degree hybrid coupler from which a radio-frequency signal of an advanced phase is output is connected to an input node of the peak amplifier, and
wherein the output node of the 90-degree hybrid coupler from which a radio-frequency signal of a delayed phase is output is connected to an input node of the carrier amplifier via the second transmission line.

5. The Doherty amplifier circuit according to claim 1,
wherein the peak amplifier is a differential amplifier, and
wherein the voltage and current conversion circuit comprises:
a peak-amplifier transformer comprising a second primary inductor connected between two output nodes of the differential amplifier and a second secondary inductor having one end connected to ground and another end connected to the second end,
a first input-side capacitor connected in parallel to the second primary inductor, and
a first output-side capacitor connected in parallel to the second secondary inductor.

6. The Doherty amplifier circuit according to claim 1, further comprising:
a high-level peak amplifier having an operation starting power level higher than an operation starting power level of the peak amplifier,
wherein an output node of the high-level peak amplifier is connected to the second end.

7. The Doherty amplifier circuit according to claim 1, further comprising:
a second input-side capacitor connected between the first end and the second end; and
a second output-side capacitor inserted between the fourth end and the output terminal.
